(19) United States
(12) Patent Application Publication
(10) Pub. No.: US 2026/0282911 A1
(43) Pub. Date: Sep. 17, 2026

(54) BONDING SHEET AND HEAT DISSIPATION MEMBER

(71) Applicants: SHINKO ELECTRIC INDUSTRIES CO., LTD., Nagano (JP); Ajinomoto Co., Inc., Tokyo (JP)

(72) Inventors: Takamasa Nagasawa, Nagano (JP); Satoru Oohashi, Kanagawa (JP); Manami Okuno, Kanagawa (JP)

(21) Appl. No.: 19/667,752

(22) Filed: May 5, 2026

Related U.S. Application Data
(63) Continuation of application No. PCT/JP2024/039730, filed on Nov. 8, 2024.

(30) Foreign Application Priority Data
Nov. 10, 2023 (JP) 2023-192444

(51) Int. Cl. H10W 40/25; F28F 21/02; H10W 40/20

(52) U.S. Cl. CPC H10W 40/257; F28F 21/02; H10W 40/242

(57) ABSTRACT

A bonding sheet includes a pair of bonding agent layers and a plurality of thermal conductors each having a linear shape. The pair of bonding agent layers are formed using a resin composition and face each other. One end of each of the plurality of thermal conductors is covered with one of the pair of bonding agent layers, and another end of each of the plurality of thermal conductors is covered with another of the pair of bonding agent layers. The resin composition contains (A) a thermosetting resin, (B) a thermoplastic resin having a glass transition temperature of 50° C. or more, and (C) a thermoplastic resin having a glass transition temperature of less than 50° C.

### CROSS-REFERENCE TO RELATED APPLICATIONS

This application is a continuation of International Application No. PCT/JP2024/039730, filed on Nov. 8, 2024 which claims the benefit of priority of the prior Japanese Patent Application No. 2023-192444, filed on Nov. 10, 2023, the entire contents of which are incorporated herein by reference.

### FIELD

The present invention relates to a bonding sheet and a heat dissipation member.

### BACKGROUND

From the viewpoint of improving heat dissipation, a heat dissipation component, such as a heat spreader, is generally fixed to an electronic component, such as a semiconductor chip. The heat dissipation component is bonded to an electronic component as a target to be bonded by, for example, a bonding sheet including: a pair of bonding agent layers formed using a resin composition; and a plurality of carbon nanotubes extending from one of the pair of bonding agent layers to the other thereof. Bonding by the bonding sheet is realized by thermally curing the bonding agent layer of the bonding sheet.

Patent Literature 1: JP 2017-228563 A

However, the above-described bonding sheet has room for improvement in reducing damage to a target to be bonded due to heat during bonding.

### SUMMARY

According to an aspect of an embodiment, a bonding sheet includes a pair of bonding agent layers being formed using a resin composition and facing each other; and a plurality of thermal conductors each having a linear shape, one end of each of the plurality of thermal conductors being covered with one of the pair of bonding agent layers, another end of each of the plurality of thermal conductors being covered with another of the pair of bonding agent layers, wherein the resin composition contains: a component (A): a thermosetting resin, a component (B): a thermoplastic resin having a glass transition temperature of 50° C. or more, and a component (C): a thermoplastic resin having a glass transition temperature of less than 50° C.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view illustrating a configuration of a bonding sheet according to an embodiment.

FIG. 2 is a view illustrating a configuration of a heat dissipation member according to the embodiment.

FIG. 3 is a view illustrating a configuration of a semiconductor device according to the embodiment.

FIG. 4 is a table indicating blending ratios of resin compositions (varnishes) according to an Example and Comparative Examples 1 to 7.

FIG. 5 is a graph illustrating a relationship between the thickness and the thermal resistance of bonding sheets according to Comparative Examples 3 to 7 and an Example.

FIG. 6 is an enlarged photograph of a bonding portion between the bonding sheet according to the Example and a heat dissipation component.

FIG. 7 is a table indicating the shear strength of the bonding sheets according to Comparative Example 3 and the Example.

### DESCRIPTION OF EMBODIMENTS

Hereinafter, embodiments of a bonding sheet and a heat dissipation member disclosed in the present application will be described in detail with reference to the drawings. Note that the disclosed technology is not limited by the embodiments.

### Configuration of Bonding Sheet

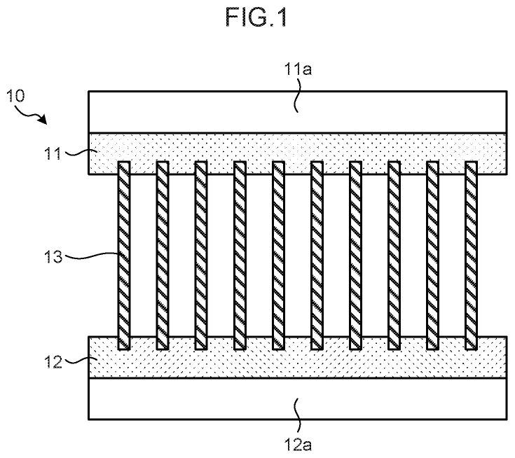

FIG. 1 is a view illustrating a configuration of a bonding sheet 10 according to an embodiment. FIG. 1 schematically illustrates a section of the bonding sheet 10. The bonding sheet 10 illustrated in FIG. 1 includes a pair of bonding agent layers 11 and 12 and a plurality of carbon nanotubes 13.

The pair of bonding agent layers 11 and 12 are formed using a resin composition and face each other. A protective film 11a is provided on a surface of the bonding agent layer 11 opposite to a surface facing the bonding agent layer 12. A protective film 12a is provided on a surface of the bonding agent layer 12 opposite to a surface facing the bonding agent layer 11. As the protective films 11a and 12a, for example, the following can be used: a polyethylene terephthalate film treated with a silicone-based release agent or a non-silicone-based release agent (hereinafter referred to as a “release PET film”). The resin composition for forming the bonding agent layers 11 and 12 will be described later.

The plurality of carbon nanotubes 13 are linear and cylindrical crystals made of carbon and are formed using a Si substrate or the like by, for example, a chemical vapor deposition (CVD) method. The plurality of carbon nanotubes 13 are disposed adjacent to each other such that the longitudinal direction of each of the plurality of carbon nanotubes 13 is oriented to the thickness direction of the bonding agent layers 11 and 12. One end of the carbon nanotube 13 is covered with the bonding agent layer 11, and the other end of the carbon nanotube 13 is covered with the bonding agent layer 12. The carbon nanotube 13 is a thermal conductor having properties in which thermal conductivity in the longitudinal direction is higher than thermal conductivity in other directions. The plurality of carbon nanotubes 13 may be, for example, carbon fibers. As the carbon fiber, for example, fullerene and graphite may be used in addition to the carbon nanotube 13.

### Resin Composition

The resin composition for forming the bonding agent layers 11 and 12 contains (A) a thermosetting resin, (B) a thermoplastic resin having a glass transition temperature of 50° C. or more, and (C) a thermoplastic resin having a glass transition temperature of less than 50° C.

Since the bonding sheet 10 includes the bonding agent layers 11 and 12 formed using the resin composition containing the components (A) to (C), damage to a target to be bonded due to heat during bonding can be reduced.

The resin composition for forming the bonding agent layers 11 and 12 may further contain (D) a curing agent, (E) a curing accelerator, (F) an inorganic filler, (G) a coupling agent, and (H) other additives, as needed.

The glass transition temperature (Tg) of the thermosetting resin and the thermoplastic resin in the present disclosure can be measured by a differential scanning calorimeter (DSC) in accordance with JIS K 7121 (2012). Specifically, X-DSC7000 (manufactured by Seiko Instruments Inc.) is used as a measuring device. A pan for DSC measurement enclosing a sample of a thermosetting resin or a thermoplastic resin is set in this device, and the temperature is raised to 270° C. at a temperature raising rate of 5°C/min under a nitrogen atmosphere. Then, the temperature at the intersection of the following two lines is defined as a “glass transition temperature”: a straight line obtained by extending the baseline on the low temperature side to the high temperature side; and a tangent line drawn at a point where the gradient of the curve in the stepwise change portion of the glass transition is the largest.

Hereinafter, each component contained in the resin composition will be described in detail.

### <(A) Thermosetting Resin>

The resin composition for forming the bonding agent layers 11 and 12 contains (A) the thermosetting resin. In the present embodiment, examples of the component (A) include epoxy resins, cyanate ester resins, phenol resins, bismaleimide-triazine resins, polyimide resins, acrylic resins, and vinylbenzyl resins. Among them, epoxy resins are preferable from the viewpoint of curability at a low temperature and the like. These thermosetting resins may be used singly or in combination of two or more. A thermosetting resin having a low glass transition temperature tends to suppress warpage, but such a thermosetting resin reduces the reflow resistance of the cured product. Therefore, a thermosetting resin having a glass transition temperature of 50° C. or more is preferably used. The glass transition temperature of the thermosetting resin is more preferably 55° C. or more, still more preferably 60° C. or more, particularly preferably 70° C. or more. The upper limit of the glass transition temperature of the thermosetting resin is not particularly limited, but is preferably 400° C. or less, more preferably 350° C. or less, still more preferably 300° C. or less, from the viewpoint of processability and handleability.

The content of the thermosetting resin having a glass transition temperature of 50° C. or more with respect to the entire thermosetting resin is preferably 60 wt % or more, more preferably 70 mass % or more, still more preferably 80 mass % or more, particularly preferably 90 mass % or more, per 100 wt % of the thermosetting resin to be used in the resin composition.

The epoxy resin is not particularly limited, and epoxy resins having two or more epoxy groups per molecule on average can be used. Examples of the epoxy resin include hydrogenated epoxy resins (hydrogenated bisphenol A epoxy resin, hydrogenated bisphenol F epoxy resin, and the like), fluorine-containing epoxy resins, chain aliphatic epoxy resins, cycloaliphatic epoxy resins, bisphenol A epoxy resins, biphenyl epoxy resins, biphenyl aralkyl epoxy resins, fluorene epoxy resins, naphthol epoxy resins, naphthalene epoxy resins, bisphenol F epoxy resins, epoxy resins containing a hydrocarbon chain as a main skeleton, phosphorus-containing epoxy resins, bisphenol S epoxy resins, aromatic glycidyl amine epoxy resins (e.g., tetraglycidyl diaminodiphenylmethane, triglycidyl-p-aminophenol, diglycidyltoluidine, and diglycidylaniline), alicyclic epoxy resins, phenol novolac epoxy resins, alkylphenol epoxy resins, cresol novolac epoxy resins, bisphenol A novolac epoxy resins, epoxy resins having a butadiene structure, diglycidyl ethers of bisphenols, diglycidyl ethers of naphthalenediols, diglycidyl ethers of phenols, diglycidyl ethers of alcohols, and alkyl-substituted products of these epoxy resins.

These epoxy resins may be used singly or in combination of two or more. The epoxy equivalent of the epoxy resin is preferably 50 to 5000, more preferably 50 to 3000, still more preferably 80 to 2000, particularly preferably 100 to 1500, from the viewpoint of reactivity and the like. The “epoxy equivalent” is the number of grams (g/eq) of a resin containing 1-gram equivalent of an epoxy group and is measured in accordance with the method specified in JIS K 7236. The weight-average molecular weight of the epoxy resin is preferably 5000 or less.

The weight-average molecular weight is measured by a gel permeation chromatography (GPC) method (in terms of polystyrene). Specifically, the weight-average molecular weight by the GPC method is measured at a column temperature of 40° C. using LC-9A/RID-6A manufactured by Shimadzu Corporation as measuring devices, Shodex K-800P/K-804L/K-804L manufactured by Showa Denko K.K. as columns, chloroform or the like as a mobile phase, and can be calculated using a calibration curve of standard polystyrene.

From the viewpoint of imparting toughness to the resin composition, the content of the thermosetting resin in the resin composition of the present disclosure is preferably 10 to 70 mass %, more preferably 15 to 65 mass %, still more preferably 20 to 60 mass %, per 100 mass % of the nonvolatile content of the resin composition.

### <(B) Thermoplastic Resin Having Glass Transition Temperature of 50° C. or More>

The resin composition for forming the bonding agent layers 11 and 12 contains (B) the thermoplastic resin having a glass transition temperature of 50° C. or more. In the present embodiment, examples of the component (B) include phenoxy resins, polyvinyl acetal resins, polyimide resins, polyamideimide resins, polyethersulfone resins, polysulfone resins, polyester resins, and (meth)acrylic polymers, all of which have a glass transition temperature of 50° C. or more. These thermoplastic resins may be used singly or in combination of two or more. The use of the thermoplastic resin having a glass transition temperature of 50° C. or more can form the resin composition into a sheet form.

The glass transition temperature of the thermoplastic resin is preferably 55° C. or more, more preferably 60° C. or more, still more preferably 70° C. or more, from the viewpoint of ensuring that the resin composition has an appropriate rigidity. The upper limit of the glass transition temperature of the thermoplastic resin is not particularly limited, but is preferably 500° C. or less, more preferably 400° C. or less, still more preferably 300° C. or less, from the viewpoint of processability and handleability.

The weight-average molecular weight of the thermoplastic resin having a glass transition temperature of 50° C. or more is preferably 15000 or more, more preferably 20000 or more, from the viewpoint of, for example, imparting flexibility to the resin composition layer formed from the resin composition, and the coatability (properties to prevent cissing) of the resin composition varnish in preparation of the bonding sheet. However, too large weight-average molecular weight tends to reduce compatibility between the thermoplastic resin having a glass transition temperature of 50° C. or more and the thermosetting resin (in particular, an epoxy resin). Therefore, the weight-average molecular weight is preferably 1000000 or less, more preferably 800000 or less.

As the thermoplastic resin having a glass transition temperature of 50° C. or more, a phenoxy resin having a glass transition temperature of 50° C. or more is preferable from the viewpoint of, for example, good compatibility with the thermosetting resin (in particular, an epoxy resin).

The phenoxy resin having a glass transition temperature of 50° C. or more may also have an epoxy group similarly to the epoxy resin as a thermosetting resin. The weight-average molecular weight of the phenoxy resin having a glass transition temperature of 50° C. or more is preferably 10000 to 500000, more preferably 20000 to 300000.

Examples of suitable phenoxy resins having a glass transition temperature of 50° C. or more include those having one or more skeletons selected from a bisphenol A skeleton, a bisphenol F skeleton, a bisphenol S skeleton, a bisphenol acetophenone skeleton, a novolac skeleton, a biphenyl skeleton, a fluorene skeleton, a dicyclopentadiene skeleton, and a norbornene skeleton. The phenoxy resins having a glass transition temperature of 50° C. or more may be used singly or in combination of two or more.

Examples of commercially available products of the phenoxy resin having a glass transition temperature of 50° C. or more include “YX7200B35” (manufactured by Mitsubishi Chemical Corporation: biphenyl skeleton-containing phenoxy resin), “1256” (manufactured by Mitsubishi Chemical Corporation: bisphenol A skeleton-containing phenoxy resin), “YX6954BH35” (manufactured by Mitsubishi Chemical Corporation: bisphenol acetophenone skeleton-containing phenoxy resin), “FX-293” (manufactured by NIPPON STEEL Chemical & Material CO., LTD.: bisphenol A skeleton-containing resin), and “FX-310” (manufactured by NIPPON STEEL Chemical & Material CO., LTD.: bisphenol A skeleton-containing resin).

As the thermoplastic resin having a glass transition temperature of 50° C. or more, a polyester resin having a glass transition temperature of 50° C. or more is also preferable from the viewpoint of, for example, good compatibility with the thermosetting resin (in particular, an epoxy resin).

Examples of the polyester resin having a glass transition temperature of 50° C. or more include “UE-9200”, “UE-3600”, “UE-9800”, “UE-9900”, “UE-9820”, “UE-3550”, and “UE-3380” (all manufactured by UNITIKA LTD.: saturated copolymeric polyester resin).

From the viewpoint of forming the resin composition into a sheet form, the content of the thermoplastic resin having a glass transition temperature of 50° C. or more in the resin composition of the present disclosure is preferably 3 to 50 mass %, more preferably 4 to 45 mass %, still more preferably 5 to 40 mass %, per 100 mass % of the nonvolatile content of the resin composition.

### <(C) Thermoplastic Resin Having Glass Transition Temperature of Less Than 50° C.>

The resin composition for forming the bonding agent layers 11 and 12 contains (C) the thermoplastic resin having a glass transition temperature of less than 50° C. In the present embodiment, examples of the component (C) include phenoxy resins, polyvinyl acetal resins, polyimide resins, polyamideimide resins, polyethersulfone resins, polysulfone resins, polyester resins, and (meth)acrylic polymers, all of which have a glass transition temperature of less than 50° C. These thermoplastic resins may be used singly or in combination of two or more. By using the thermoplastic resin having a glass transition temperature of less than 50° C. in combination with the thermoplastic resin having a glass transition temperature of 50° C. or more, adhesiveness can be maintained at the time of bonding a substrate and forming an insulating layer, particularly at the time of bonding substrates of different materials and forming an insulating layer.

From the viewpoint of the effect of the present invention, the glass transition temperature of the thermoplastic resin is preferably 45° C. or less, more preferably 40° C. or less, still more preferably 30° C. or less. The lower limit of the glass transition temperature of the thermoplastic resin is not particularly limited as long as the effect of the present invention is exerted, but is preferably −50°C or more, more preferably −40°C or more, still more preferably −30°C or more, from the viewpoint of heat resistance of the resin composition.

The weight-average molecular weight of the thermoplastic resin having a glass transition temperature of less than 50° C. is preferably 15000 or more, more preferably 20000 or more, from the viewpoint of, for example, imparting flexibility to the resin composition layer formed from the resin composition, and the coatability (properties to prevent cissing) of the resin composition varnish in preparation of the bonding sheet. However, too large weight-average molecular weight tends to reduce compatibility between the thermoplastic resin having a glass transition temperature of less than 50° C. and the thermosetting resin (in particular, an epoxy resin). Therefore, the weight-average molecular weight is preferably 1000000 or less, more preferably 800000 or less.

As the thermoplastic resin having a glass transition temperature of less than 50° C., a phenoxy resin having a glass transition temperature of less than 50° C. is preferable from the viewpoint of, for example, good compatibility with a thermosetting resin (in particular, an epoxy resin).

The phenoxy resin having a glass transition temperature of less than 50° C. may also have an epoxy group similarly to the epoxy resin as a thermosetting resin. The weight-average molecular weight of the phenoxy resin having a glass transition temperature of less than 50° C. is preferably 10000 to 500000, more preferably 20000 to 300000.

Examples of suitable phenoxy resins having a glass transition temperature of less than 50° C. include those having one or more skeletons selected from a bisphenol A skeleton, a bisphenol F skeleton, a bisphenol S skeleton, a bisphenol acetophenone skeleton, a novolac skeleton, a biphenyl skeleton, a fluorene skeleton, a dicyclopentadiene skeleton, and a norbornene skeleton. The phenoxy resins having a glass transition temperature of less than 50° C. may be used singly or in combination of two or more.

Examples of a commercially available product of the phenoxy resin having a glass transition temperature of less than 50° C. include “YX7180BH40” (manufactured by Mitsubishi Chemical Corporation).

As the thermoplastic resin having a glass transition temperature of less than 50° C., a polyester resin having a glass transition temperature of less than 50° C. is also preferable from the viewpoint of, for example, good compatibility with a thermosetting resin (in particular, an epoxy resin).

Examples of the polyester resin having a glass transition temperature of less than 50° C. include “UE-3510”, “UE-3400”, “UE-3220”, “UE-3500”, and “UE-9100” (all manufactured by UNITIKA LTD.: saturated copolymeric polyester resin).

From the viewpoint of forming the resin composition into a sheet form, the content of the thermoplastic resin having a glass transition temperature of 50° C. or more in the resin composition of the present invention is preferably 3 to 50 mass %, more preferably 4 to 45 mass %, still more preferably 5 to 40 mass %, per 100 mass % of the nonvolatile content of the resin composition.

### <(D) Curing Agent>

The resin composition for forming the bonding agent layers 11 and 12 may contain (D) the curing agent. The component (D) is not particularly limited as long as the component (D) has a function of curing the thermosetting resin. From the viewpoint of suppressing the amount of generation of warpage or thermal strain, a component that can cure the thermosetting resin at a temperature of 140° C. or less (preferably 120° C. or less; i.e., a curing agent that can cure the thermosetting resin at a low temperature) is preferable as the curing agent.

As an example of the curing agent, a curing agent for an epoxy resin preferable as a thermosetting resin is provided. Examples of the curing agent include ionic liquids, acid anhydride compounds, imidazole compounds, tertiary amine compounds, dimethylurea compounds, amine adduct compounds, organic acid dihydrazide compounds, organic phosphine compounds, dicyandiamide compounds, and primary and secondary amine compounds. The curing agents may be used singly or in combination of two or more. The curing agent that can cure the thermosetting resin at a low temperature is preferably one or more selected from ionic liquids, acid anhydride compounds, imidazole compounds, tertiary amine compounds, dimethylurea compounds, and amine adduct compounds, more preferably one or more selected from ionic liquids, acid anhydride compounds, imidazole compounds, tertiary amine compounds, and dimethylurea compounds.

The content of the curing agent in the resin composition of the present disclosure is preferably 0.1 to 40 mass %, more preferably 0.5 to 38 parts by mass, still more preferably 1 to 35 parts by mass, per 100 mass % of the nonvolatile content of the resin composition. The content of less than 0.1 mass % may lead to insufficient curability, and the content of more than 40 mass % may impair the storage stability of the resin composition.

### <(E) Curing Accelerator>

The resin composition for forming the bonding agent layers 11 and 12 may contain (E) the curing accelerator in addition to (D) the curing agent, for the purpose of, for example, adjusting the curing time. As an example of the curing accelerator, a curing accelerator for an epoxy resin preferable as a thermosetting resin is provided. Examples of the curing accelerator include imidazole compounds, tertiary amine compounds, dimethylurea compounds, and amine adduct compounds. The curing accelerators may be used singly or in combination of two or more.

When the resin composition of the present disclosure contains the curing accelerator, the content of the curing accelerator is preferably 0.05 to 10 mass %, more preferably 0.1 to 8 mass %, still more preferably 0.5 to 5 mass %, per 100 mass % of the nonvolatile content of the resin composition. The content of less than 0.05 mass % tends to slow curing and lengthen the thermal curing time, and the content of more than 10 mass % tends to reduce the storage stability of the resin composition.

The resin composition in the present disclosure is preferably used in combination of (D) the curing agent and (E) the curing accelerator. A combination of the curing agent that can cure the thermosetting resin at a low temperature and the curing accelerator is preferably two or more selected from ionic liquids, acid anhydride compounds, imidazole compounds, tertiary amine compounds, dimethylurea compounds, and amine adduct compounds.

Examples of the cation constituting the ionic liquid as the curing agent in the present invention include ammonium cations, such as an imidazolium ion, a piperidinium ion, a pyrrolidinium ion, a pyrazonium ion, a guanidinium ion, and a pyridinium ion; phosphonium cations, such as tetraalkylphosphonium cations (e.g., a tetrabutylphosphonium ion and a tributylhexylphosphonium ion); and sulfonium cations, such as a triethylsulfonium ion.

Examples of the anion constituting the ionic liquid as the curing agent in the present invention include halide anions, such as a fluoride ion, a chloride ion, a bromide ion, and an iodide ion; alkyl sulfate anions, such as a methanesulfonate ion; fluorine-containing compound anions, such as a trifluoromethanesulfonate ion, a hexafluorophosphonate ion, a trifluorotris(pentafluoroethyl)phosphonate ion, a bis(trifluoromethanesulfonyl)imide ion, a trifluoroacetate ion, and a tetrafluoroborate ion; phenolic anions, such as a phenol ion, a 2-methoxyphenol ion, and a 2,6-di-tert-butylphenol ion; acidic amino acid ions, such as an aspartate ion and a glutamate ion; neutral amino acid ions, such as a glycine ion, an alanine ion, and a phenylalanine ion; N-acylamino acid ions represented by the following general formula (1), such as an N-benzoylalanine ion, an N-acetylphenylalanine ion, and an N-acetylglycine ion; and carboxylate anions, such as a formate ion, an acetate ion, a decanoate ion, a 2-pyrrolidone-5-carboxylate ion, an α-lipoate ion, a lactate ion, a tartrate ion, a hippurate ion, an N-methylhippurate ion, and a benzoate ion.

Examples of the acid anhydride compound as the curing agent in the present invention include tetrahydrophthalic anhydride, methyltetrahydrophthalic anhydride, hexahydrophthalic anhydride, methylhexahydrophthalic anhydride, methylnadic anhydride, and dodecenylsuccinic anhydride. Specific examples of the acid anhydride compound include RIKACID TH, TH-1A, HH, MH, MH-700, and MH-700G (all manufactured by New Japan Chemical Co., Ltd.).

Examples of the imidazole compound as the curing agent and the curing accelerator in the present invention include 1H-imidazole, 2-methyl-imidazole, 2- phenyl-4-methylimidazole, 2-ethyl-4-methylimidazole, 1-cyanoethyl-2-ethyl-4-methyl-imidazole, 2-undecylimidazole, 1-cyanoethyl-2-undecylimidazole, 1-cyanoethyl-2-undecylimidazolium trimellitate, 2,4-diamino-6-(2′-undecylimidazolyl-(1′))-ethyl-s-triazine, 2-phenyl-4,5-bis(hydroxymethyl)-imidazole, 1-benzyl-2-methylimidazole, 1-benzyl-2-phenylimidazole, 2-phenyl-imidazole, 2-dodecyl-imidazole, 2-heptadecylimidazole, 1,2-dimethyl-imidazole, 2-phenyl-4-methyl-5-hydroxymethylimidazole, 2,4-diamino-6-(2′-methylimidazolyl-(1′))-ethyl-s-triazine, and 2,4-diamino-6-(2′-methylimidazolyl-(1′))-ethyl-s-triazine isocyanuric acid adduct. Specific examples of the imidazole compound include CUREZOL 2MZ, 2P4MZ, 2E4MZ, 2E4MZ-CN, C 11Z, C 11Z-CN, C 11Z-CNS, C 11Z-A, 2PHZ, 1B 2MZ, 1B 2PZ, 2PZ, C 17Z, 1.2DMZ, 2P 4MHZ-PW, 2MZ-A, and 2MA-OK (all manufactured by SHIKOKU CHEMICALS CORPORATION).

Specific examples of the tertiary amine compound as the curing agent and the curing accelerator in the present invention include 1,5-diazabicyclo[4.3.0]non-5-ene (DBN); 1,8-diazabicyclo[5.4.0]undec-7-ene (DBU); DBU-organic acid salts, such as 2-ethylhexanoate of DBU, a phenol salt of DBU, p-toluenesulfonate of DBU, U-CAT SA 102 (manufactured by San-Apro Ltd.: octylate of DBU), and formate of DBU; and tris(dimethylaminomethyl)phenol (TAP).

Specific examples of the dimethylurea compound as the curing agent and the curing accelerator in the present invention include aromatic dimethylureas, such as 3-(3,4-dichlorophenyl)-1,1-dimethylurea (DCMU) and U-CAT 3512T (manufactured by San-Apro Ltd.); and aliphatic dimethylureas, such as U-CAT 3503N (manufactured by San-Apro Ltd.). Among them, aromatic dimethylureas are preferably used from the viewpoint of curability.

Examples of the amine adduct compound as the curing agent and the curing accelerator in the present invention include an epoxy adduct compound obtained by stopping the addition reaction of a tertiary amine to an epoxy resin in the middle. Specific examples of the amine adduct compound include AJICURE PN-23, AJICURE MY-24, AJICURE PN-D, AJICURE MY-D, AJICURE PN-H, AJICURE MY-H, AJICURE PN-31, AJICURE PN-40, and AJICURE PN-40J (all manufactured by Ajinomoto Fine-Techno Co., Inc.).

### <(F) Inorganic Filler>

The resin composition for forming the bonding agent layers 11 and 12 may further contain (F) the inorganic filler. Examples of such an inorganic filler include uncalcined hydrotalcite, semi-calcined hydrotalcite, calcined hydrotalcite, talc, silica, alumina, barium sulfate, clay, mica, aluminum hydroxide, magnesium hydroxide, calcium carbonate, magnesium carbonate, boron nitride, aluminum borate, barium titanate, strontium titanate, calcium titanate, magnesium titanate, bismuth titanate, titanium oxide, zirconium oxide, barium zirconate, calcium zirconate, and silicate. The inorganic fillers may be used singly or in combination of two or more. The particle diameter of the primary particles of the inorganic filler is preferably 5 μm or less, more preferably 3 μm or less. For example, an inorganic filler whose primary particles have a particle diameter of 0.001 to 3 μm can be used, and an inorganic filler whose primary particles have a particle diameter of 0.005 to 2 μm can be more preferably used.

The particle form of the inorganic filler is not particularly limited, and the inorganic filler having any of the following particle forms can be used: a substantially spherical shape, a rectangular parallelepiped shape, a plate shape, a linear shape such as a fiber, or a branched shape. The inorganic filler is preferably talc, silica, zeolite, titanium oxide, alumina, zirconium oxide, silicate, mica, magnesium hydroxide, aluminum hydroxide, or the like, more preferably talc or silica, particularly preferably talc. As the silica, amorphous silica, fused silica, crystalline silica, synthetic silica, wet silica, dry silica, and colloidal silica (those dispersed in water or an organic solvent, fumed silica, and the like) are preferable. From the viewpoint of being less likely to precipitate and settle and being easily combined with a resin, colloidal silica dispersed in an organic solvent (organosilica sol) is particularly preferable.

As the inorganic filler, those surface-treated with a surface treatment agent can be used. As the surface treatment agent used for the surface treatment, for example, higher fatty acids, alkylsilanes, and silane coupling agents can be used. Among them, higher fatty acids and alkylsilanes are suitable. The surface treatment agents may be used singly or in combination of two or more.

### <(G) Coupling Agent>

The resin composition for forming the bonding agent layers 11 and 12 may contain (G) the coupling agent. Examples of the coupling agent include a silane coupling agent, an aluminate coupling agent, and a titanate coupling agent.

The content of the coupling agent in the resin composition of the present disclosure is preferably 0 to 15 mass %, more preferably 0.5 to 10 mass %, per 100 mass % of the nonvolatile content of the resin composition.

### <(H) Other Additives>

The resin composition for forming the bonding agent layers 11 and 12 may further contain other additives different from the above-described components. Examples of such additives include organic fillers, such as rubber particles, silicone powder, nylon powder, and fluororesin powder; thickeners, such as ORBEN and BENTONE; silicone-based, fluorine-based, or polymer-based antifoaming agents or leveling agents; adhesion promoters, such as a triazole compound, a thiazole compound, a triazine compound, and a porphyrin compound; and flame retardants, such as a phosphorus-based compound and a metal hydroxide.

### Method of Producing Resin Composition

The method of producing the resin composition of the present disclosure is not particularly limited. Examples of the method include a method of mixing the blending components, or as needed, the blending components to which a solvent or the like is added, by using a kneading roller, a rotary mixer, or the like.

### Characteristics of Bonding Agent Layer

The bonding agent layers 11 and 12 formed using the resin composition of the present disclosure exhibit a characteristic of being curable at a temperature of 150° C. or less (preferably 120° C. or less). For example, the thermal curing conditions of the bonding agent layers 11 and 12 vary depending on the type of the resin composition and the like, but the curing temperature is in the range of 50° C. to 150° C., and the curing time is in the range of 5 minutes to 120 minutes.

If a bonding agent layer is formed using another resin composition different from the resin composition of the present disclosure, the bonding agent layer is not cured at a temperature of 150° C. or less. The bonding agent layers 11 and 12 of the embodiment are formed using the resin composition containing the components (A) to (C). As a result, the bonding agent layers 11 and 12 can be cured at a temperature of 150° C. or less (preferably 120° C. or less), and therefore the bonding sheet 10 can reduce damage to a target to be bonded due to heat during bonding.

As described above, the bonding sheet 10 according to the embodiment can reduce damage to a target to be bonded due to heat during bonding. Therefore, the bonding sheet 10 according to the embodiment can be suitably used, for example, as a bonding sheet when a heat dissipation member is bonded to an electronic component, such as a semiconductor chip, as a target to be bonded.

### Method of Producing Bonding Sheet

To obtain the bonding sheet 10, first, the resin composition of the present disclosure is blended with an organic solvent to obtain a varnish-form resin composition. The varnish-form resin composition is then applied onto a protective film (e.g., the protective film 11a or the protective film 12a). Then, the obtained coating film (varnish) is dried by heating or hot air spraying to form a resin composition layer (e.g., the bonding agent layer 11 or the bonding agent layer 12) on the protective film. Subsequently, both ends of the plurality of carbon nanotubes (e.g., the carbon nanotubes 13) are covered with the bonding agent layer to obtain the bonding sheet 10 described above.

Examples of the protective film used for the bonding sheet 10 include plastic films of: polyolefins, such as polyethylene, polypropylene, and polyvinyl chloride; cycloolefin polymers; polyesters, such as polyethylene terephthalate (hereinafter may be abbreviated as “PET”) and polyethylene naphthalate; polycarbonate; and polyimide. As the plastic film, PET is particularly preferable. The protective film may be a metal foil, such as an aluminum foil, a stainless steel foil, or a copper foil. The protective film may be subjected to a treatment including: a release treatment with a silicone resin-based release agent, an alkyd resin-based release agent, a fluororesin-based release agent, or the like; a mat treatment; or a corona treatment. The thickness of the protective film is not particularly limited, but is preferably 20 to 200 μm, more preferably 20 to 125 μm, from the viewpoint of handleability and the like.

Examples of the organic solvent include ketones, such as acetone, methyl ethyl ketone (hereinafter also abbreviated as “MEK”), and cyclohexanone; acetic esters, such as ethyl acetate, butyl acetate, cellosolve acetate, propylene glycol monomethyl ether acetate, and carbitol acetate; carbitols, such as cellosolve and butyl carbitol; aromatic hydrocarbons, such as toluene and xylene; dimethylformamide; dimethylacetamide; and N-methylpyrrolidone. Any one of the organic solvents may be used alone, or two or more thereof may be used in combination.

The drying conditions are usually and suitably, but are not particularly limited to, at about 50 to 100° C. and for about 3 to 15 minutes.

The thickness of the resin composition layer (bonding agent layer) after drying is usually in the range of 3 μm to 200 μm, preferably 5 μm to 100 μm, more preferably 5 μm to 50 μm.

The resin composition layer (bonding agent layer) is usually cured by thermal curing. Examples of the thermal curing means include heating by a hot air circulation oven, an infrared heater, a heat gun, a high frequency induction heating device, and pressure bonding with a heating tool. From the viewpoint of bonding the cured resin composition layer (cured product layer) to the target to be bonded with sufficient bonding strength, the curing temperature is preferably 50° C. or more, more preferably 55° C. or more, and the curing time is preferably 10 minutes or longer, more preferably 20 minutes or longer.

### Configuration of Heat Dissipation Member

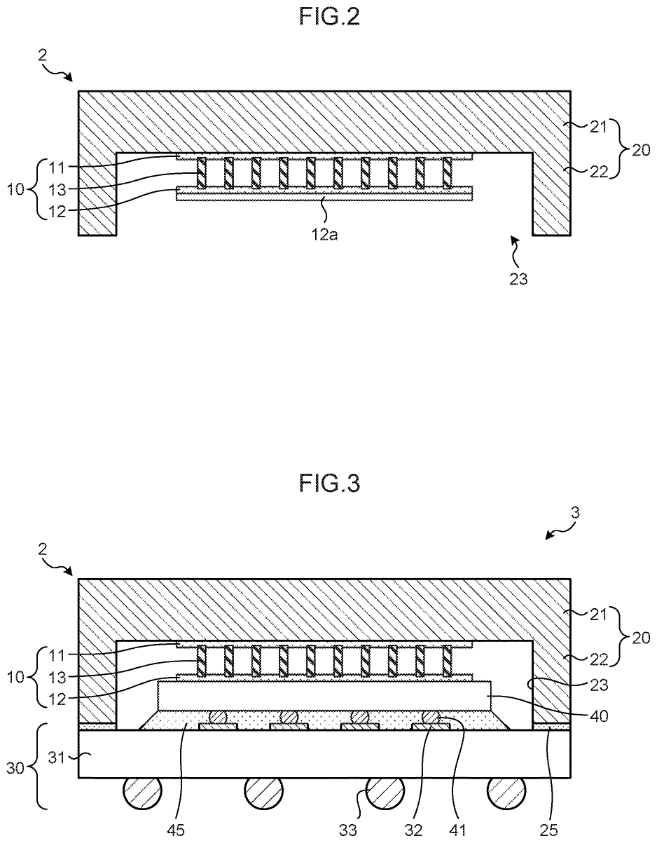

FIG. 2 is a view illustrating a configuration of a heat dissipation member 2 according to the embodiment. FIG. 2 schematically illustrates a section of the heat dissipation member 2. The heat dissipation member 2 illustrated in FIG. 2 includes a heat dissipation plate 20 and the bonding sheet 10.

The heat dissipation plate 20 is a heat dissipation component also called a heat spreader. As a material of the heat dissipation plate 20, a material having a good thermal conductivity is preferable. As a material of the heat dissipation plate 20, for example, copper (Cu), silver (Ag), aluminum (Al), and an alloy thereof can be used. As a material of the heat dissipation plate 20, a non-metal material can also be used as long as the material has a good thermal conductivity.

The heat dissipation plate 20 includes a plate-shaped portion 21 and a frame-shaped side wall portion 22 formed on a peripheral edge of the plate-shaped portion 21, and a recess 23 for accommodating a semiconductor chip is formed by the plate-shaped portion 21 and the side wall portion 22.

The bonding sheet 10 is bonded to the heat dissipation plate 20. Specifically, after the protective film 11a is peeled off from the bonding agent layer 11, the exposed surface of the bonding agent layer 11 is bonded to the bottom surface of the recess 23 of the heat dissipation plate 20.

### Configuration of Semiconductor Device

The heat dissipation member 2 can be suitably used as a heat dissipation member in a semiconductor device including an electronic component, such as a semiconductor chip. FIG. 3 is a view illustrating a configuration of a semiconductor device 3 according to the embodiment. FIG. 3 schematically illustrates a section of the semiconductor device 3. The semiconductor device 3 illustrated in FIG. 3 includes a wiring substrate 30, a semiconductor chip 40, and the heat dissipation member 2.

The wiring substrate 30 includes a substrate body 31, connection pads 32, and solder balls 33. The substrate body 31 has a structure in which the connection pads 32 and the solder balls 33 are electrically connected to each other through the inside of the substrate body 31. The wiring layer may be formed inside the substrate body 31, but the wiring layer is not necessarily formed. When a wiring layer is formed inside the substrate body 31, a plurality of wiring layers are laminated with an interlayer insulating layer interposed between adjacent ones of the plurality of wiring layers. The connection pads 32 and the solder balls 33 are electrically connected to each other by the wiring layers and the vias formed in the interlayer insulating layers. As the substrate body 31, for example, a build-up substrate with a core including a core substrate and a coreless substrate not including a core substrate can be used.

The connection pad 32 is formed on the upper surface of the substrate body 31 for mounting the semiconductor chip 40. When the semiconductor chip 40 is mounted on the upper surface of the wiring substrate 30, connection terminals 41 of the semiconductor chip 40 are connected to the respective connection pads 32. As a material of the connection pad 32, for example, copper (Cu) or a copper alloy can be used.

The solder balls 33 are formed on the lower surface of the substrate body 31. As a material of the solder ball 33, for example, the following can be used: an alloy containing lead (Pb); an alloy of tin (Sn) and copper (Cu); an alloy of tin (Sn) and silver (Ag); and an alloy of tin (Sn), silver (Ag), and copper (Cu). The solder ball 33 forms, for example, an external connection terminal connected to an external component, such as a motherboard.

For example, the semiconductor chip 40 has the following structure. On a thinned semiconductor substrate made of silicon (Si) or the like, an element formation surface (here, the lower surface) side on which a semiconductor integrated circuit (not illustrated) is formed is covered with a passivation film. The connection terminals 41 are disposed on the element formation surface.

As the semiconductor chip 40, for example, logic chips can be used. The logic chips include a central processing unit (CPU) chip and a graphics processing unit (GPU) chip. As the semiconductor chip 40, for example, memory chips can also be used. The memory chips include a dynamic random access memory (DRAM) chip, a static random access memory (SRAM) chip, and a flash memory chip. The size of the semiconductor chip 40 is, for example, about 10 mm×10 mm in plan view. The thickness of the semiconductor chip 40 can be set to, for example, 10 to 50 μm.

For example, the semiconductor chip 40 is flip-chip mounted on the wiring substrate 30. In other words, the semiconductor chip 40 is electrically connected to the connection pads 32 of the wiring substrate 30 through the connection terminals 41. As the connection terminal 41, for example, a gold (Au) bump or a solder bump can be used. As a material of the solder bump, for example, the following can be used: an alloy containing lead (Pb); an alloy of tin (Sn) and copper (Cu); an alloy of tin (Sn) and silver (Ag); and an alloy of tin (Sn), silver (Ag), and copper (Cu).

An underfill resin 45 is filled between the lower surface of the semiconductor chip 40 and the upper surface of the wiring substrate 30. As a material of the underfill resin 45, for example, an insulating resin, such as an epoxy resin, can be used.

The heat dissipation member 2 is disposed above the semiconductor chip 40. In other words, after the protective film 12a is peeled off from the bonding agent layer 12 of the bonding sheet 10 in the heat dissipation member 2, the exposed surface of the bonding agent layer 12 is bonded to the upper surface of the semiconductor chip 40. Then, the bonding agent layer 12 is thermally cured. In this way, the heat dissipation member 2 is bonded to the semiconductor chip 40 as a target to be bonded by the bonding sheet 10.

The bonding sheet 10 includes the bonding agent layers 11 and 12 formed using the resin composition containing the components (A) to (C). As a result, the bonding agent layers 11 and 12 can be cured at a temperature of 140° C. or less (preferably 120° C. or less), and therefore the bonding sheet 10 can reduce damage to a target to be bonded (i.e., the semiconductor chip 40) due to heat during bonding.

The heat dissipation member 2 may be mounted on the wiring substrate 30. In this case, the heat dissipation plate 20 of the heat dissipation member 2 may be bonded to the peripheral edge portion of the wiring substrate 30 with a bonding agent 25 so as to surround the semiconductor chip 40. As a material of the bonding agent 25, for example, a silicon polymer-based resin can be used.

The semiconductor chip 40 is accommodated in the recess 23 formed on the heat dissipation plate 20 of the heat dissipation member 2.

### Various Characteristics of Bonding Sheet

Hereinafter, various characteristics of the bonding sheet will be specifically described with reference to an Example of the bonding sheet including the bonding agent layer formed using the resin composition containing the components (A) to (C), and Comparative Examples 1 to 7 of the bonding sheet including the bonding agent layer formed using another resin composition. Note that the present disclosure is not limited to the following Example. In the following description, “part(s)” and “%” in the amount of components mean “part(s) by mass” and “mass %”, respectively, unless otherwise specified.

### EXAMPLE

### Components

The components used in an Example and Comparative Examples 1 to 7 are stated below.
(A) Thermosetting resin:
Mixture of a liquid bisphenol A epoxy resin and a liquid bisphenol F epoxy resin (“ZX-1059” manufactured by Nippon Steel Chemical Co., Ltd., epoxy equivalent: about 165, Tg: 155° C.)
(B) Thermoplastic resin having a glass transition temperature of 50° C. or more:
Phenoxy resin solution (“YX7200B35” manufactured by Mitsubishi Chemical Corporation, solvent: MEK, nonvolatile content: 35%, Tg: 156° C.)
(C) Thermoplastic resin having a glass transition temperature of less than 50°C:
Phenoxy resin solution (“YX7180BH40” manufactured by Mitsubishi Chemical Corporation, solvent: mixed solvent of MEK and cyclohexanone, nonvolatile content: 40%, Tg: 15° C.)
(D) Curing agent:
“2E4MZ” manufactured by SHIKOKU CHEMICALS CORPORATION
“Ail-01” manufactured by Ajinomoto Fine-Techno Co., Inc.
(E) Curing accelerator:
“U-CAT 3512T” manufactured by San-Apro Ltd.
“Salicylic acid” manufactured by FUJIFILM Wako Pure Chemical Corporation
(F) Inorganic filler:
“SO-C2” manufactured by ADMATECHS COMPANY LIMITED
(G) Coupling agent:
“KBM-573” manufactured by Shin-Etsu Chemical Co., Ltd.

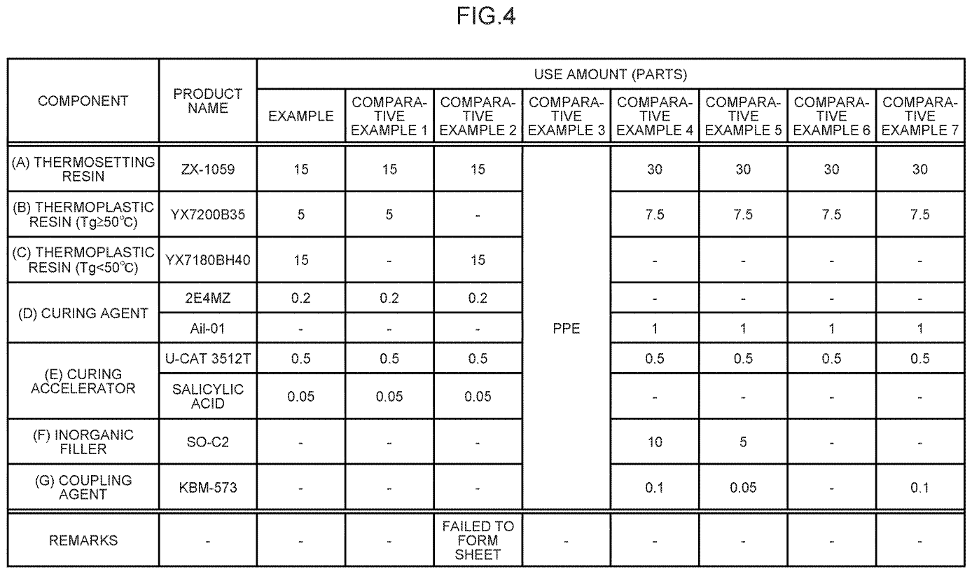

In the Example, a varnish having a blending ratio indicated in FIG. 4 was prepared by the following procedure, a bonding agent layer was prepared using the obtained varnish, and both ends of a plurality of carbon nanotubes were covered with the bonding agent layer to prepare a bonding sheet. FIG. 4 is a table indicating blending ratios of resin compositions (varnishes) according to the Example and Comparative Examples 1 to 7. Note that the use amount (part) of each component described in FIG. 4 indicates the amount of the nonvolatile content of each component in the varnish.

Specifically, a mixture of a liquid bisphenol A epoxy resin and a liquid bisphenol F epoxy resin (“ZX-1059” manufactured by Nippon Steel Chemical Co., Ltd.), a phenoxy resin solution (“YX7200B35” manufactured by Mitsubishi Chemical Corporation), and a phenoxy resin solution (“YX7180BH40” manufactured by Mitsubishi Chemical Corporation) were blended, and a uniformly dispersed mixture was obtained using a high-speed rotating mixer. The obtained mixture was blended with a curing accelerator (“U-CAT 3512T” manufactured by San-Apro Ltd. and “salicylic acid” manufactured by FUJIFILM Wako Pure Chemical Corporation) and a curing agent (“2E4MZ” manufactured by SHIKOKU CHEMICALS CORPORATION), and the mixture was uniformly dispersed using a high-speed rotating mixer to obtain a varnish of a resin composition.

The obtained varnish was uniformly applied onto a release surface of a release PET film as a protective film by using a die coater so that the thickness of the dried resin composition layer is 20μm. Then, the coating film of the varnish was dried at 80° C. for 10 minutes to form a resin composition layer (bonding agent layer) on the release surface of the release PET film.

Subsequently, a plurality of carbon nanotubes were formed by using a Si substrate or the like by, for example, a CVD method, and both ends of the carbon nanotubes were covered with the bonding agent layer to obtain a bonding sheet according to the Example.

### Comparative Example 1

A thermosetting bonding sheet in which the thickness of the resin composition layer was 20 μm was prepared by the same method as in Example except that the blending of the resin composition was changed to have a composition from which the phenoxy resin solution (“YX7180BH40” manufactured by Mitsubishi Chemical Corporation) was excluded.

### Comparative Example 2

An attempt was made to prepare a thermosetting bonding sheet by the same method as in Example except that the blending of the resin composition was changed to have a composition from which the phenoxy resin solution (“YX7200B35” manufactured by Mitsubishi Chemical Corporation) was excluded. However, formation of a thermosetting bonding sheet was difficult.

### Comparative Example 3

In Comparative Example 3, a varnish of a polyphenylene ether (PPE) resin was prepared by the following procedure, a bonding agent layer was prepared using the obtained varnish, and both ends of a plurality of carbon nanotubes were covered with the bonding agent layer to prepare a bonding sheet.

Specifically, the PPE resin was uniformly dispersed by using a high-speed rotating mixer to obtain a varnish of the resin composition.

The obtained varnish was uniformly applied onto a release surface of a release PET film as a protective film by using a die coater so that the thickness of the dried resin composition layer is 20μm. Then, the coating film of the varnish was dried at 80° C. for 10 minutes to form a resin composition layer (bonding agent layer) on the release surface of the release PET film.

Subsequently, a plurality of carbon nanotubes were formed by using a Si substrate or the like by, for example, a CVD method, and both ends of the carbon nanotubes were covered with the bonding agent layer to obtain a bonding sheet according to Comparative Example 3.

### Comparative Example 4

A thermosetting bonding sheet in which the thickness of the resin composition layer was 20 μm was prepared by the same method as in Example except that the blending of the resin composition was changed as follows:
Changed the use amount (parts) of the mixture of a liquid bisphenol A epoxy resin and a liquid bisphenol F epoxy resin (“ZX-1059” manufactured by Nippon Steel Chemical Co., Ltd.)
Changed the use amount (parts) of the phenoxy resin solution (“YX7200B35” manufactured by Mitsubishi Chemical Corporation)
Excluded the phenoxy resin solution (“YX7180BH40” manufactured by Mitsubishi Chemical Corporation)
Used a curing agent (“Ail-01” manufactured by Ajinomoto Fine-Techno Co., Inc.)
Excluded the curing accelerator (“salicylic acid” manufactured by FUJIFILM Wako Pure Chemical Corporation)
Used an inorganic filler (“SO-C2” manufactured by ADMATECHS COMPANY LIMITED)
Used a coupling agent (“KBM-573” manufactured by Shin-Etsu Chemical Co., Ltd.)

### Comparative Example 5

A thermosetting bonding sheet in which the thickness of the resin composition layer was 20 μm was prepared by the same method as in Comparative Example 4 except that the blending of the resin composition was changed as follows:
Changed the use amount (parts) of the inorganic filler (“SO-C2” manufactured by ADMATECHS COMPANY LIMITED)
Changed the use amount (parts) of the coupling agent (“KBM-573” manufactured by Shin-Etsu Chemical Co., Ltd.)

### Comparative Example 6

A thermosetting bonding sheet in which the thickness of the resin composition layer was 20 μm was prepared by the same method as in Comparative Example 4 except that the blending of the resin composition was changed as follows:
Excluded the inorganic filler (“SO-C2” manufactured by ADMATECHS COMPANY LIMITED)
Excluded the coupling agent (“KBM-573” manufactured by Shin-Etsu Chemical Co., Ltd.)

### Comparative Example 7

A thermosetting bonding sheet in which the thickness of the resin composition layer was 20 μm was prepared by the same method as in Comparative Example 4 except that the blending of the resin composition was changed as follows:
Excluded the inorganic filler (“SO-C2” manufactured by ADMATECHS COMPANY LIMITED)

### Thermal Curing Conditions of Bonding Sheets According to Comparative Examples 1 and 3 and Example

The bonding agent layers in the bonding sheets according to Comparative Examples 1 and 3 and Examples were thermally cured. The curing temperature used to thermally cure the bonding agent layer is 100° C., and the curing time is 60 minutes. As a result, in the bonding sheet according to the Example, the thermal curing of the bonding agent layer was confirmed to be completed. Here, the completion of thermal curing of the bonding agent layer means that the hardness of the bonding agent layer is a predetermined hardness or more. On the other hand, in the bonding sheets according to Comparative Examples 1 and 3, the thermal curing of the bonding agent layers was confirmed to be not yet completed at the curing temperature of 100° C. and the curing time of 60 minutes. Here, the incompletion of thermal curing of the bonding agent layer means that the hardness of the bonding agent layer is less than a predetermined hardness.

As described above, in the bonding sheet according to the Example, the bonding agent layer was curable at a temperature of 100° C. Therefore, the use of the bonding sheet according to the Example can reduce damage to a target to be bonded due to heat during bonding.

### Heat Dissipation Performance of Bonding Sheets According to Comparative Examples 3 to 7 and Example

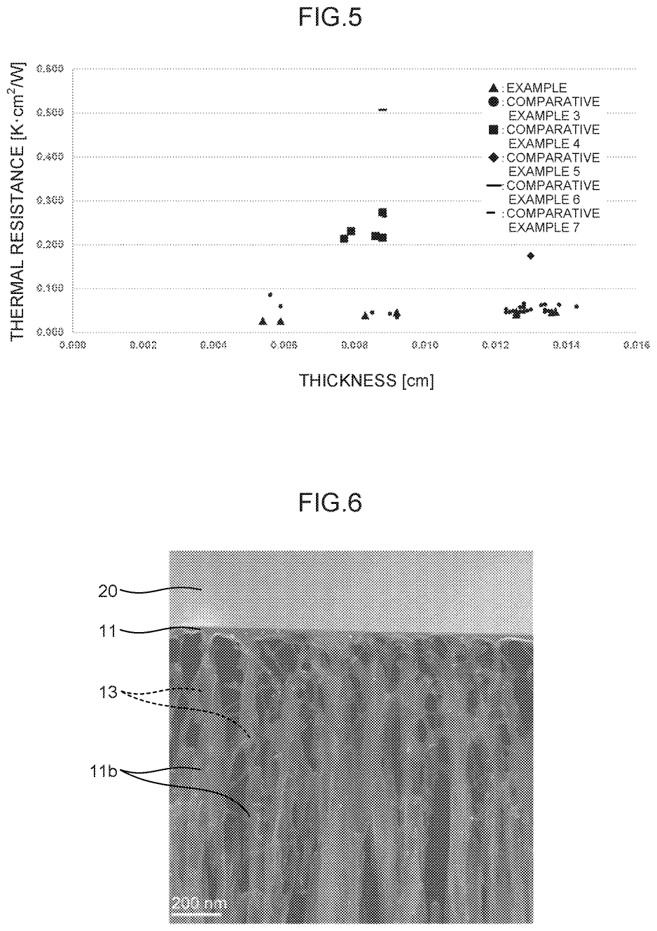

The relationship between the thickness and the thermal resistance of the bonding sheets according to Comparative Examples 3 to 7 and the Example was examined by an experiment. FIG. 5 is a graph illustrating a relationship between the thickness and the thermal resistance of the bonding sheets according to Comparative Examples 3 to 7 and the Example. In the experiment of FIG. 5, a plurality of bonding sheets with different thicknesses according to Comparative Examples 3 to 7 and the Example were prepared, and the thermal resistance was measured for each bonding sheet of each thickness. The thermal resistance was measured in a state where each bonding sheet of each thickness was bonded to the heat dissipation component (e.g., the heat dissipation plate 20). As a result, the bonding sheets according to the Example were confirmed to have lower thermal resistance than the bonding sheets according to Comparative Examples 3 to 7. This leads to a finding that the bonding sheet according to the Example has an excellent heat dissipation performance compared to the bonding sheets according to Comparative Examples 3 to 7.This is considered to be because, as illustrated in FIG. 6, the resin composition (e.g., a resin composition 11b) for forming the bonding agent layer (e.g., the bonding agent layer 11) of the bonding sheet according to the Example was sucked up by the carbon nanotubes 13 due to capillary action, and the thickness of the bonding agent layer (e.g., the bonding agent layer 11) between the heat dissipation plate 20 and the carbon nanotubes 13 was reduced. FIG. 6 is an enlarged photograph of a bonding portion between the bonding sheet according to the Example and a heat dissipation component. As illustrated in FIG. 6, the carbon nanotubes 13 are covered with a resin composition (e.g., the resin composition 11b) sucked up by the carbon nanotubes 13 due to capillary action.

### Adhesion Strength of Bonding Sheets According to Comparative Example 3 and Example

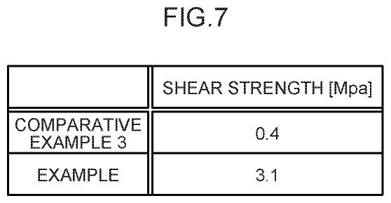

The shear strength of the bonding sheets according to Comparative Example 3 and the Example was examined by an experiment. FIG. 7 is a table indicating the shear strength of bonding sheets according to Comparative Example 3 and the Example. In the experiment of FIG. 7, a member made of copper (Cu) was bonded to one of the pair of bonding agent layers of the bonding sheets according to Comparative Example 3 and the Example, a member made of aluminum (Al) was bonded to the other, and the shear strength of each bonding sheet was measured. As a result, the bonding sheet according to the Example was confirmed to have shear strength about eight times larger than the bonding sheet according to Comparative Example 3. This leads to a finding that the bonding sheet according to the Example has larger adhesion strength to a member than the bonding sheet according to Comparative Example 3.

As described above, the bonding sheet (as an example, the bonding sheet 10) according to the embodiment includes a pair of bonding agent layers (as an example, the bonding agent layers 11 and 12) and a plurality of thermal conductors each having a linear shape (as an example, the carbon nanotubes 13). The pair of bonding agent layers are formed using a resin composition and face each other. One end of each of the plurality of thermal conductors is covered with one of the pair of bonding agent layers, and the other end of each of the plurality of thermal conductors is covered with the other of the pair of bonding agent layers. The resin composition contains (A) a thermosetting resin, (B) a thermoplastic resin having a glass transition temperature of 50° C. or more, and (C) a thermoplastic resin having a glass transition temperature of less than 50° C. This configuration can reduce damage to a target to be bonded due to heat during bonding.

One aspect of the bonding sheet disclosed in the present application has an effect of reducing damage to a target to be bonded due to heat during bonding.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A bonding sheet comprising:
a pair of bonding agent layers being formed using a resin composition and facing each other; and
a plurality of thermal conductors each having a linear shape, one end of each of the plurality of thermal conductors being covered with one of the pair of bonding agent layers, another end of each of the plurality of thermal conductors being covered with another of the pair of bonding agent layers, wherein the resin composition contains:
a component (A): a thermosetting resin,
a component (B): a thermoplastic resin having a glass transition temperature of 50° C. or more, and
a component (C): a thermoplastic resin having a glass transition temperature of less than 50°C.

2. The bonding sheet according to claim 1, wherein
the component (A) is one or more resins selected from epoxy resins, cyanate ester resins, phenol resins, bismaleimide-triazine resins, polyimide resins, acrylic resins, and vinylbenzyl resins.

3. The bonding sheet according to claim 1, wherein
the component (B) is one or more resins selected from phenoxy resins, polyvinyl acetal resins, polyimide resins, polyamideimide resins, polyethersulfone resins, polysulfone resins, polyester resins, and (meth)acrylic polymers, all of which have a glass transition temperature of 50° C. or more.

4. The bonding sheet according to claim 1, wherein
the component (C) is one or more resins selected from phenoxy resins, polyvinyl acetal resins, polyimide resins, polyamideimide resins, polyethersulfone resins, polysulfone resins, polyester resins, and (meth)acrylic polymers, all of which have a glass transition temperature of less than 50° C.

5. The bonding sheet according to claim 1, wherein the plurality of thermal conductors are carbon fibers.

6. A heat dissipation member comprising:
a heat dissipation component; and
a bonding sheet being bonded to the heat dissipation component, wherein
the bonding sheet includes:
a pair of bonding agent layers being formed using a resin composition and facing each other, and
a plurality of thermal conductors each having a linear shape, one end of each of the plurality of thermal conductors being covered with one of the pair of bonding agent layers, another end of each of the plurality of thermal conductors being covered with another of the pair of bonding agent layers, and
the resin composition contains:
a component (A): a thermosetting resin,
a component (B): a thermoplastic resin having a glass transition temperature of 50° C or more, and
a component (C): a thermoplastic resin having a glass transition temperature of less than 50° C.
